(19) United States
(12) Patent Application Publication
(10) Pub. No.: US 2012/0111386 A1
(43) Pub. Date: May 10, 2012

(54) ENERGY MANAGEMENT SYSTEMS AND METHODS WITH THERMOELECTRIC GENERATORS

(76) Inventors: Lon E. Bell, Altadena, CA (US); Douglas T. Crane, Altadena, CA (US); Dmitri Kossakovski, S. Pasadena, CA (US); Darrell Park, S. Pasadena, CA (US); John LaGrandeur, Arcadia, CA (US)

(21) Appl. No.: 13/289,380

(22) Filed: Nov. 4, 2011

Related U.S. Application Data
(60) Provisional application No. 61/410,773, filed on Nov. 5, 2010.

(51) Int. Cl. H01L 35/30; G06F 1/26

(52) U.S. Cl. 136/205; 700/297

(57) ABSTRACT

In some embodiments, an integrated power generation system includes a primary power source supplying power to a primary power user, a thermoelectric power generator system thermally coupled to a heat source, and an electronic controller unit. In certain embodiments, an electronic controller unit monitors the power output of the primary power source and operatively connects the thermoelectric power generating system to the primary power user when one or more power usage factors occurs. One power usage factor that can occur is the power output of the primary power source falling below a threshold power level.

### RELATED APPLICATION

This application claims the benefit under 35 U.S.C. §119(e) of U.S. Provisional Application No. 61/410,773, filed Nov. 5, 2010, titled INTEGRATED WASTE HEAT RECOVERY AND POWER GENERATION, the entire contents of which are incorporated by reference herein and made part of this specification.

### BACKGROUND

1. Field

This disclosure generally relates to energy management systems that incorporate one or more thermoelectric devices.

2. Description of Related Art

Power equipment commonly produces waste heat in addition to a desired output. For example, a motor vehicle typically converts fuel energy into mechanical energy and waste heat. Commercial power plants typically generate electrical power and waste heat from coal, natural gas, nuclear fission, wind power, solar power, geothermal power, or other power sources. Heating, ventilation, and air conditioning systems and water heaters typically generate waste heat in addition to conditioned fluid.

At least a portion of the waste heat is often removed from power equipment through an exhaust system or heat sink. In motor vehicles, additional processing of exhaust after its removal from the power plant, including chemical reactions and emissions reduction techniques, can heat the exhaust and increase the amount of waste heat. For a vehicle having a combustion engine, the exhaust system usually includes tubing that carries exhaust gases away from a controlled combustion inside the engine. The exhaust gases and waste heat can be carried along an exhaust pipe and expelled into the environment.

Thermoelectric (TE) power generation systems generate electrical power by exploiting processes that convert thermal flux from temperature differences into electrical power (e.g., the Seebeck effect). TE power generation systems can be made, for example, by attaching off-the-shelf thermoelectric devices onto the side of a structure that provides a source of heat. At least some existing thermoelectric generators (TEGs) are not very efficient or flexible in their operation.

### SUMMARY

Embodiments described herein have several features, no single one of which is solely responsible for all of their desirable attributes. Without limiting the scope of the disclosed embodiments, some of the advantageous features will now be discussed briefly.

Some embodiments relate to energy management systems that include a primary power source and one or more thermoelectric devices (TEDs). The primary power source can be, for example, a power plant (e.g., a combustion power plant, a solar energy power plant, a wind power plant, a geothermal power plant, or another type of power plant), an engine (e.g., a vehicle engine, a gasoline engine, a diesel engine, a boat engine, a tank engine, a locomotive engine, or another type of engine), a boiler, a furnace, a burner, another power source, or a combination of power sources.

Some embodiments provide energy management systems and methods that include a primary power source and a solid state power generation system (SSG). The solid state power generation system (SSG) can include materials that are configured to convert thermal power into electric power, such as, for example, thermoelectric materials. As used herein, the terms thermoelectric device (TED), thermoelectric element (TE element), thermoelectric generator (TEG), and thermoelectric power generation system (TEG) are used in their broad and ordinary sense. For example, TEDs, TE elements, and TEGs can include traditional solid state energy conversion systems and/or related solid state technologies, such as thermionic systems, thermomagnetic systems, electrocaloric systems, another solid state system, or a combination of systems that convert thermal power into electrical power. A TEG can sometimes be called a thermoelectric power generation system or thermoelectric power generator system (TPG).

An energy management system can be configured to use an SSG in one or more modes of operation. For example, in some modes of operation, the system uses the SSG to convert at least a portion of the waste heat generated by a primary power source into electrical energy. In certain modes of operation, the system uses the SSG to convert at least a portion of a primary output of the primary power source into electrical power, where the primary output is thermal energy. In some such modes of operation, the conversion of the primary output into electrical power occurs before, after, and/or simultaneously with another use of the primary output. In some embodiments, the system uses the SSG to generate auxiliary electrical power when the primary power source is at less than full operation or inoperable. In certain embodiments, the system uses the SSG to generate additional electrical power when the primary power source is at substantially at full capacity operation. In some embodiments, the thermal output of the SSG is used to improve the efficiency and/or operation of the primary power source.

In an embodiment an integrated power generation system includes a primary power source (PPS), which may be a fluctuating power source (FPS), configured to provide power to a primary power user (PPU), an SSG configured to generate electrical power from thermal power, and an electronic controller unit (ECU) configured to implement a power distribution protocol. In some embodiments, the power distribution protocol is configured to operatively connect the SSG to the PPU, upon the occurrence one or more power usage factors.

In some embodiments, the one or more power usage factors includes the demand for power exceeding a threshold demand level, the power output of the PPS falling below a threshold power level, or the PPS being turned off. In some embodiments, the threshold power level is determined based on at least one of previous average power output levels, expected power output levels, and demand by the PPU. In certain embodiments, the threshold demand level is determined based on the power output capacity of the PPS. In some embodiments, the ECU is configured to operatively connect the SSG to an auxiliary power user (APU) upon the occurrence of a one or more additional power usage factors. In some embodiments, the one or more additional power usage factors include the power demanded by the APU exceeding the power supplied to the APU. In some embodiments, at least one of the one or more additional power usage factors is the same as the first one or more power usage factors. In some embodiments, the APU receives power from a power source other than the PPS.

In some embodiments, an integrated power generation system includes an energy storage device. In some embodiments, the energy storage device stores thermal energy from a heat source. In some embodiments, the energy storage device stores electrical energy generated by the SSG. In some embodiments, the ECU is configured to operatively connect the SSG to a power distribution grid (PDI). In some embodiments, the PDI is a local power grid. In some embodiments, the SSG is located in close proximity to at least one of the PPU and the PPS. In some embodiments, the SSG is located in remotely from at least one of the PPU and the PPS. In some embodiments, the ECU is located remotely from at least one of the PPU and the PPS. In some embodiments, the ECU is embedded as part of at least one of the SSG and the PPS. In some embodiments, the heat source is one of a machine, a roof, ambient air, a burner, a heater, and ground. In some embodiments, the ECU is in communication with multiple SSG. In some embodiments, the SSG comprises multiple SSG.

In some embodiments, a method for supplying power to a primary power user includes supplying power from an FPS to a PPU, monitoring the power output of the FPS, adjusting supply of power to the PPU according to a power distribution protocol. In some embodiments, the power distribution protocol includes operatively connecting a SSG to the PPU, according to one or more power usage factors. In some embodiments, the one or more power usage factors include the power demand exceeding a threshold demand level or the power output of the PPS falling below a threshold power level.

In some embodiments, a TEG configured to supply power to a PPU includes one or more TEDs configured to generate electrical power using temperature differentials when coupled to a heat source, and an ECU configured to direct the electrical power generated by the one or more TEDs to a PPU upon receiving a communication that the power output of a PPS connected to the PPU is below a threshold power level.

### BRIEF DESCRIPTION OF THE DRAWINGS

Various embodiments are depicted in the accompanying drawings for illustrative purposes, and should in no way be interpreted as limiting the scope of the inventions. In addition, various features of different disclosed embodiments can be combined to form additional embodiments, which are part of this disclosure. Any feature or structure can be removed or omitted. Throughout the drawings, reference numbers may be reused to indicate correspondence between reference elements.

FIG. 1 schematically illustrates an embodiment of an energy management system incorporating a primary power source and a thermoelectric generator.

FIG. 2 schematically illustrates an embodiment of an energy management system having a waste heat recovery mode and an auxiliary electric energy generation mode.

FIG. 3A schematically illustrates an embodiment of an energy management system configured to generate electrical power and heat output.

FIG. 3B schematically illustrates an embodiment of an energy management system connected to a thermal power utilization system.

FIG. 4 schematically illustrates an embodiment of an energy management system having a thermoelectric generator and a thermal storage device.

FIG. 5A is a schematic diagram of an embodiment of an integrated power system.

FIG. 5B is a schematic diagram illustrative of various embodiments of an integrated power system.

FIG. 6 is a graph showing an example power output of an integrated power system.

FIG. 7 is a schematic block diagram illustrating an embodiment of an integrated power system.

FIG. 8 is a flow diagram illustrating an embodiment of a method for controlling an allocation of power generated by a thermoelectric power generation system.

FIG. 9 is a schematic diagram showing various modes in which an integrated power system can operate.

### DETAILED DESCRIPTION

Although certain preferred embodiments and examples are disclosed herein, inventive subject matter extends beyond the specifically disclosed embodiments to other alternative embodiments and/or uses of the inventions, and to modifications and equivalents thereof. Thus, the scope of the inventions herein disclosed is not limited by any of the particular embodiments described below. For example, while some energy management system and method embodiments are described with reference to a TEG or TPG, it is understood that any SSG can be used in addition to or in place of a TEG or TPG. As another example, in any method or process disclosed herein, the acts or operations of the method or process may be performed in any suitable sequence and are not necessarily limited to any particular disclosed sequence.

For purposes of contrasting various embodiments with the prior art, certain aspects and advantages of these embodiments are described. Not necessarily all such aspects or advantages are achieved by any particular embodiment. Thus, for example, various embodiments may be carried out in a manner that achieves or optimizes one advantage or group of advantages as taught herein without necessarily achieving other aspects or advantages as may also be taught or suggested herein. While some of the embodiments are discussed in the context of particular sensor and switch configurations, it is understood that the inventions may be used with other system configurations.

Electrical power is generated in a variety of ways to meet different demands. For example, electrical power for commercial, residential, and industrial use is typically generated at a primary power source, such as a power plant, using nuclear, gas, coal, wind, geothermal, solar and/or other energy, etc. The generated electrical power from the primary power source is then provided to users via power lines. At certain times of the day or year, there is a greater demand for electrical power. During these times, primary power sources are often unable to provide sufficient power to meet immediate user demand. In addition, some power sources, such as renewable power sources, can be affected by environmental conditions, such as clouds or a lack of wind, and be unable to supply sufficient energy to meet user demand. In either case, power shortages can result in insufficient energy being supplied to the users, creating brownouts or even blackouts.

Electrical power can also be generated on a much smaller scale to power a local area or object, such as a house, vehicle, etc. To generate electrical power at this scale the primary power source can be a relatively small generator, such as a gas-powered generator. For vehicles, such as cars, personal or commercial trucks, recreational vehicles (RVs), campers, and the like, the primary power source is often a vehicle engine, battery, or alternator. In some instances, a user may prefer to turn off their primary power source, but still want to use electronic devices that require electrical power. For example, a truck driver may sleep in his truck overnight, and want to use one or more devices that require electrical power, such as a TV, audio or video player, air conditioner, fan, and the like. Leaving the truck engine running can be wasteful as the electrical devices may use only a fraction of the power produced by the truck engine. In some embodiments, the truck driver may use electrical power from the truck battery to power his electronic devices. However, the truck battery may be unable to provide sufficient energy to power the devices for an extended period of time, such as throughout the night.

Whether the primary power source is a power plant supplying electrical power to various commercial, industrial, and/or residential areas, or a relatively small generator or engine supplying electrical power to a local area or object, demand may exceed the energy output of the primary power source. As mentioned above, this may result from excessive use by many users due to weather conditions, environmental conditions preventing a renewable power source from properly generating electrical power, or from a user wishing to conserve energy from the primary power source but still wanting to use one or more electrical devices. In any case, there is insufficient electrical power to meet demand.

A TEG can be used in one or more modes to provide auxiliary electrical power when the electrical power from the primary power source is insufficient. The TEG can use ambient thermal power produced by a heat source or primary power source to generate electrical power. In certain embodiments, a thermal power source, such as, for example, a burner can be used to generate the thermal power that is then converted to electrical power by the TEG.

In a primary mode, the TEG can be used for waste heat recovery, as a temperature control device, to supply electrical power to supplement the electrical power provided by the PPS, or sit idly. In a secondary mode, the TEG can function as the primary power source to meet electrical power demands of an area or object when the PPS is non-functional or the use of the PPS is not desired.

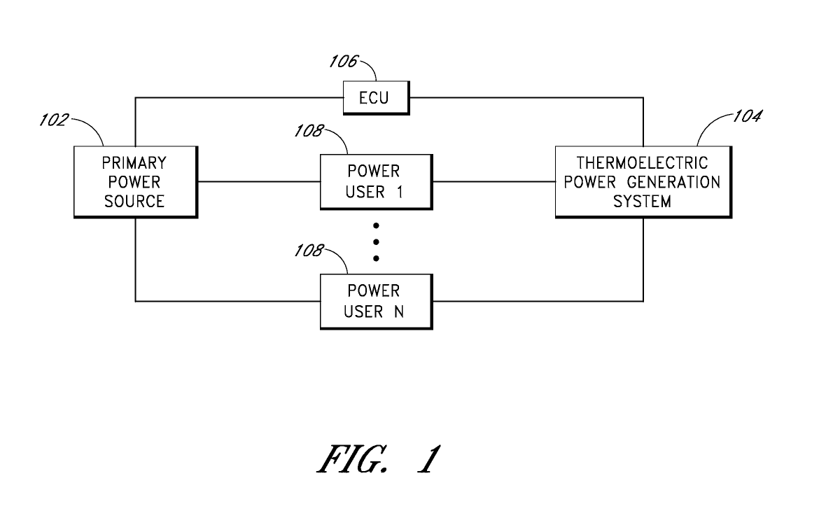

FIG. 1 is a block diagram illustrative of an embodiment of an integrated power system (IPS) including a PPS 102, a TEG 104, an ECU 106, and any number of PPU 108. In IPS can include any power system that includes a PPS and a TEG. Many variations are possible. The various components of the IPS can be in direct communication with each other or may communicate via the ECU 106, or similar means. The communication can be effectuated in any number of ways such as a WAN, LAN, internet, wired or wireless network and the like. In the embodiment illustrated in FIG. 1, the ECU 106 is in communication with the PPS 102 and the communication with TEG 104.

The PPS 102 is the primary source of power for the PPU 108, and can generate power from either renewable or non-renewable power sources including solar, wind, waves, tidal, geothermal, fossil fuels, and the like. Thus, the PPS 102 can be a variety of different renewable or non-renewable power sources including a solar array, a wind farm, wave farm, tidal farm, geothermal power station, fossil fuel station, nuclear station, and the like. The PPS 108 may be a large scale power station or a small generator, such as a portable gas-powered generator, or vehicle engine. The PPS 108 can be located in close proximity to a PPU 108 or can be remotely located, as is typical for fossil-fuel power stations. In addition, the PPS 102 can provide power to only one PPU 108 or to more than one PPUs 108.

The TEG 104 converts thermal power from waste heat generated by the PPS or another heat source into electrical power, and can be local to the PPS 102 or the PPU 108. The TEG 104 includes one or more thermoelectric elements that create a voltage in the presence of a temperature difference between two different metals or semiconductors. An applied temperature difference causes charged carriers in the different metals or semiconductors to diffuse from the hot side to the cool side, resulting in thermoelectric voltage. The TEG 104 is provided, for instance, with heat energy from any number of sources, including heat energy emitted as a waste product by the PPS 102 or PPU 108, by heating or cooling devices, by exhausts, or by any devices that produces heat or cold as a by-product. The TEG 104 may also be coupled with naturally occurring heat sources, such as the roof of a building, the ground, geothermal formations, or the like. The TEG 104 can include energy storage devices that store thermal energy or electrical energy. In another embodiment, the storage devices are separate from the TEG 104.

During operation, if the PPS 102 is unable to provide sufficient power to the PPU 108, the TEG 104 can supplement the power from the PPS 102. The TEG 104 may act as an auxiliary power source and supplement the electrical power production of the PPS 102 when there is a significant load increase on the PPS 102 due to weather conditions (e.g., many users turn on their air conditioner due to hot weather), or when the PPS 102 generates less electrical power than usual (e.g., clouds are blocking a solar array). In other instances, the TEG 104 can act as a primary power source when the PPS 102 is not functioning or not activated. For example, the TEG 104 can act as a primary power source at night to replace power from a solar array, or to generate some electric power for a military tank, truck, plane, or other vehicle when the engine is turned off

The PPU 108 can include primary power users such as direct users of the system or others. The PPU 108 can also be recipients of the electrical power from the TEG 104. The PPU 108 may include, but are not limited to, industrial complexes, business and residential areas, vehicles (e.g., cars, trucks, motorcycles, boats, planes, ships, barges, etc.), and the like. In some instances, the demand of the PPU 108 exceeds the supply from the PPS 102, and additional electrical power can be provided by the TEG 104. In some embodiments, when the power output of the PPS 102 drops below a threshold power level, or power demand by the PPU 108 exceeds the power supply by the PPS 102, the TEG 104 provides electrical power to the PPU 108. If the PPU 108 does not require additional power, the TEG 104 can provide electrical power for other users, including the APU, an auxiliary storage device (ASD), and/or power distribution infrastructure (PDI). The TEG 104 may also provide electrical power to these users regardless of the state of the primary power users, depending on the one or more power usage factors.

The ECU 106 monitors the PPS 102 and TEG 104 to determine when the TEG 104 should supplement or replace the electrical power supplied by the PPS 102. In addition, the ECU 106 can monitor environmental and usage conditions to predict when electrical power from TEG 104 should be used. The ECU 106 may be located remotely from the TEG 104, the PPS 102, or both. In some embodiments, the ECU 106 may be located in close proximity to either the TEG 104 or the PPS 102.

In one embodiment, the ECU 106 is embedded within TEG 104 or the PPS 102 as part of the different components. In some embodiments, the ECU 106 is configured to control the various components of the system and their communication. The ECU 106 takes input in the form of system readings, such as power output by the PPU 102, local power grid, etc., user action or inaction, current price of electricity sold back to the local grid, current electricity usage on the premises the system serves, storage capacity, upcoming demand on the premises or from the local grid, time of day, weather conditions, and electricity production/demand estimates. The ECU 106 uses these inputs to determine the appropriate action to take with regards to operatively connecting the TEG 104 to the PPU 108.

In some embodiments, the ECU 106 monitors the TEG 104 using a power distribution protocol to determine if one or more power usage factors, or rules, have occurred. As mentioned above, the one or more power usage factors may include, but are not limited to power levels of storage devices, time of day or year, expected weather conditions, power output of the PPS 102 and/or TEG 104, whether the PPS 102 is providing power at a threshold power level, and the like. The threshold power level may be determined based on expected power levels, average power levels, demand by the PPU 108, other demand factors, or a combination of demand factors.

For example, if the ECU 106 determines that the PPS 102 is providing power at or above a threshold power level, the ECU 106 does not establish an electrical power flow between TEG 104 and the PPU 108. The ECU 106 may determine that a number or all of the PPU 108 have their electrical power requirements satisfied by the flow of electrical power from the PPS 102, by determining whether the flow of electrical power from the PPS 102 meets at least one of the one or more power usage factors. In the event that the ECU 106 determines the power supplied from the PPS 102 does not meet one or more power usage factors or that the PPS 102 is supplying less power than demanded by the PPU 108, the ECU 106 can operatively connect the TEG 104 to specific users among the PPU 108, for instance, by establishing electrical power flow between them. In some embodiments, the system switches between these two settings, depending on the one or more power usage factors.

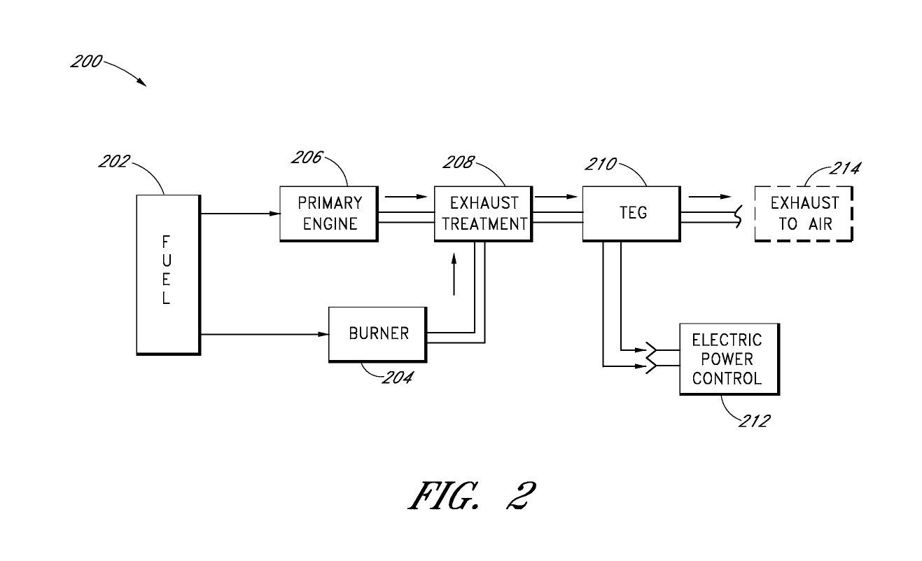

FIG. 2 is a block diagram illustrative of an embodiment of an integrated power system 200 including a fuel container 202, a fuel burner 204, a primary engine 206, an exhaust treatment system 208, a TEG 210, an electric power control 212, and an exhaust release 214. The integrated power system 200 may be used in conjunction with buildings, vehicles, or other objects that rely on an engine to provide power, but in some modes use less power than is produced by the engine. For example, trucks, tanks, and airplanes all have engines that can produce significant amounts of power when in use. However, a user may desire to use electrical devices when the engine power is off. As mentioned previously, a truck driver may wish to operate a fan in the cab of his truck to maintain a certain temperature level, military personnel may wish to have access to their navigation system equipment when the tank is powered down, and pilots may want electrical power for on board equipment when a plane's engines are off. Additionally, warehouses, factories, or business buildings may employ large engines to supply power and perform various tasks. However, in case of emergency these engines may be unable to operate, but certain security or emergency features may still be desired. In such situations, the integrated power system 200 can provide the desired electrical power.

The fuel container 202 may contain any type of appropriate combustible fuel for use by the primary engine 206 and the burner 204. For example, the fuel may be a gas, liquid, solid, slurry, or other type of fuel that can be used by the primary engine 206 and burner 204. The fuel container can provide the fuel to the primary engine 206 and burner 204 via conduits using pumps, fans, fuel injectors, conveyor systems, and the like.

The burner 204 can use fuel supplied from the fuel container 202 to generate thermal power. The burner 204 can be implemented using any number of devices capable of converting chemical energy to thermal energy. In some embodiments, the burner shares fans, pumps, fuel injectors, etc. with the primary engine 206. In certain embodiments, the burner 204 has its own fan, pump, and fuel injector. In other embodiments some components are shared between the primary engine 206 and the burner 204 and other components are not shared. For example, if the primary engine 206 is a diesel engine, fuel may be injected at very high pressure (e.g., at a pressure between about 100 atmospheres and about 300 atmospheres) while the burner 204 can operate at much lower pressures (e.g., at a pressure between about 0.1 atmospheres and about 1.0 atmospheres). As another example, the primary burner 206 may be within a turbine engine powered by natural gas at a pressure between about 3 atmospheres and about 100 atmospheres, while the burner 204 may operate at less than one atmosphere gauge pressure. In some embodiments, the burner 204 can be powered by diesel fuel or heating oil from an emergency reservoir.

The primary engine 206 may be any type of engine that generates waste heat during operation. The primary engine 206 may be a diesel engine of a truck or tank, a turbine engine, or the like, and may be used to drive a generator, power a vehicle, or the like. The waste heat that is produced during operation is fed into the exhaust treatment system 208. The exhaust treatment system 208 can be an exhaust manifold, catalytic converter, particle trap, or the like that cleans or otherwise sanitizes the exhaust from the primary engine and then expels the exhaust via release 214.

As the waste heat travels through the exhaust treatment system 208 and is expelled via the release 214, the TEG 210 can be used to convert at least some of the waste heat to electrical power. The electrical power can be sent to the electric power control 212 for use. The waste heat can be treated prior to being expelled at the release 214. The waste heat can be harvested from the exhaust stream by passing it through a suitable heat exchanger wherein the waste heat can travel in the form of a working medium, not shown, such as hot air, oil, inert gas, slurry, liquid metal or the like. The working medium, in good thermal contact with the TEG 210, would transfer waste thermal power to the TEG 210 for conversion to electrical power.

During normal operation, thermal energy can be stored in one or more thermal storage devices (not shown) for later conversion by the TEG 210 or can be converted to electrical power to supplement the power supplied by the primary engine 206. For example, the converted stored thermal energy can power the navigation system of the tank or an electric fan. If additional power is demanded, the burner 204 can be used to supply additional thermal power. Fuel from the fuel container 202 can be injected into the burner 204. The burner 204 can use the fuel to generate thermal power. In some embodiments, the thermal power from the burner is transferred to the exhaust system 208 and onto TEG 210. In certain embodiments, the thermal power from the burner 204 bypasses the exhaust system 208 and is fed directly to the TEG 210. In some embodiments, the TEG 104 powers the fan and pump to provide fuel to the burner 204. In certain embodiments, a secondary power source, such as a battery, provides the initial power to the fan and pump to transfer the fuel to the burner. Once a threshold power level is reached by the TEG 104, the TEG 104 powers the fan and pump.

In an auxiliary mode, such as when the primary engine 206 is turned off, the burner 204 and TEG 210 can be used to supply electrical power to the user. Using the burner 204 and TEG 210 to generate a smaller quantity of electrical power output than the primary engine 206 is configured to generate, the amount of fuel used can be significantly reduced, and fuel can be conserved. In some embodiments, the burner 204 and TEG 210 are used to generate the minimum amount of electrical power that can satisfy user demands. For example, when the tank engine is turned off, the fuel can be converted by the burner 204 to thermal power, which is then converted to electrical power by the TEG 210. Enough fuel can be fed to the burner 204 to generate sufficient thermal and electrical power to supply the power demanded by the user. For example, the electrical power can be used to power the navigation system for the tank. In certain embodiments, the electrical power can be used to power a radar system, communications equipment, a heater, or other electrical devices in the tank, truck, airplane, or other vehicle. If additional power is demanded, the fuel container 202 can provide additional fuel to the burner 204.

In some embodiments, the TEG 210 can be used to propel the vehicle at less than full operating capability when the vehicle propulsion system is not fully functional. During normal operation, thermal energy can be collected from vehicle batteries, the exhaust system, etc., and stored in thermal storage devices, as described above. If the engine becomes less than fully inoperable, the thermal energy stored in thermal storage devices can be converted to electrical power by the TEG and transferred to an electric motor (such as in a hybrid vehicle). In certain embodiments, the burner 204 can be supplied to combust fuel and air to generate thermal power. The thermal power can then be converted to electrical power by the TEG to power the vehicle at less than full function. Such a mode of operation can be sometimes called a “limp home” mode of operation.

Thermoelectric-based power generators can be used in a variety of ways in industrial, commercial, residential, automotive, marine, aviation, and other applications. For example, performance advances in power generation thermoelectric materials and government mandates for CO₂ emission reductions have led to increased interest in waste heat recovery systems. In particular, a waste heat recovery system that meets the requirements of the passenger vehicle, van and truck markets is desired. Preferred designs are rugged, reliable, capable of providing stable operation for at least 15 years, and cost effective. In some embodiments, a waste recovery system operates in the exhaust stream at temperatures up to 700° C. to accommodate a broad range of mass flows and is of sufficiently high efficiency to make a significant contribution to CO₂ emissions reductions.

Waste heat recovery systems can be used to recapture a portion of energy that would otherwise be lost through waste heat. A waste heat recovery system positioned in the exhaust system of a motor vehicle can meet automotive requirements and can provide useful amounts of electrical power under common driving conditions.

Governments in many countries are requiring that the transportation industry actively address fossil fuel consumption and reduce emissions, including CO₂ and other greenhouse gases. Most CO₂ initiatives, such as those in the European Community, China, Japan and the USA, require decreasing allowable levels of emissions and fuel consumption by a target date. Some embodiments address these mandates by increasing efficiency and controlling greenhouse gas emissions. The embodiments disclosed herein are effective as a source for large efficiency gains from the introduction of a single subsystem. The ability of such systems to have a large performance impact and the complexity and cost of system integration have been barriers for at least some previous waste heat recovery technologies to overcome. For example, these barriers have been present in systems based on two phase fluid (e.g., the Rankine cycle) or other solid state waste heat recovery technology.

Several factors combine to make solid state thermoelectric systems attractive. First, vehicles are becoming more electrified as part of automobile companies' strategy to reduce emissions through the use of smarter subsystems such as engine off operation during deceleration and at rest, and the adoption of electrified subsystems including brakes (regeneration and actuation), steering systems, fuel pumps, thermal management subsystems (e.g., PTC heaters) and other equipment. These changes reduce CO₂ emissions, but on average consume more electric power throughout the drive cycle. Further, electric power loads vary significantly during city drive cycles, so that electrical storage capacity is more important and flow of increased electrical power has to be managed. Some embodiments address these factors by converting waste heat directly to electric power, as opposed to mechanical power output.

Some embodiments incorporate TE materials exhibiting improved performance. Improved TE material performance can result from advances including an increase in power factor and a reduction in thermal conductivity in mid temperature (300° C. to 600° C.) materials. Some embodiments incorporate TE materials that employ reduced thermal conductivity techniques in low temperature (0° C. to 300° C.) materials. The improved TE materials can increase the amount of electric power produced from waste heat so as to have a larger contribution to efficiency gain, and in doing so, not add to system complexity or size. Thus, costs per watt of electrical power output can decrease. Further cost reductions have been demonstrated by incorporating system design technology that uses less TE material.

Some embodiments provide a waste heat recovery apparatus including an exhaust tube having a generally cylindrical outer shell configured to contain a flow of exhaust fluid. In certain embodiments, a first heat exchanger extends through a first region of the exhaust tube. The first heat exchanger can be in thermal communication with the cylindrical outer shell. A second region or bypass region of the exhaust tube can have a low exhaust fluid pressure drop. In some embodiments, an exhaust valve is operatively disposed within the second region and is configured to allow exhaust fluid to flow through the second region only when a flow rate of the exhaust fluid becomes great enough to result in back pressure beyond an allowable limit. In certain embodiments, one or more TE elements are in thermal communication with an outer surface of the outer shell. The thermoelectric elements can be configured to accommodate thermal expansion of the exhaust tube during operation of the waste heat recovery system.

In some embodiments, the apparatus includes a coolant conduit in thermal communication with the plurality of thermoelectric elements. The coolant conduit can include an inner tube and an outer tube in thermal communication with one another. The outer tube can have a greater diameter than the inner tube and include expansion joints configured to accommodate dimensional changes due to thermal expansion between the cylindrical outer shell and the coolant conduit. In some embodiments, the exhaust tube includes no expansion joints for accommodating dimensional changes due to thermal expansion.

Certain embodiments provide a waste heat recovery apparatus including an exhaust tube configured to contain a flow of exhaust fluid. The exhaust tube can have a high temperature end, a low temperature end opposite the high temperature end, and a middle section between the high temperature end and the low temperature end during operation of the waste heat recovery apparatus. A first plurality of TE elements can be connected to the high temperature end, a second plurality of TE elements can be connected to the middle section, and a third plurality of TE elements can be connected to the low temperature end. The second plurality of TE elements can be longer than the third plurality of TE elements, and the first plurality of TE elements can be longer than the second plurality of TE elements.

Some embodiments provide a waste heat recovery apparatus including a generally cylindrical exhaust tube configured to contain a flow of exhaust fluid. A bypass region can extend through the exhaust tube. The bypass region can have a low exhaust fluid pressure drop. A coolant conduit can be configured to contain a flow of coolant within a first tube. The coolant conduit can include a second tube enclosing at least a portion of the first tube and a conductive material disposed between the first tube and the second tube. A first shunt can extend from the exhaust tube. A second shunt can extend from the coolant conduit and be in thermal communication with the second tube. A thermoelectric element can be in thermal communication with the first shunt and the second shunt. The first shunt can be held against the exhaust tube by a tensioned hoop extending around the perimeter of the exhaust tube.

In certain embodiments, a TE system is provided. The TE system can include a plurality of TE elements. At least one cooler side shunt and at least one hotter side shunt can be in thermal communication with at least one of the plurality of TE elements. The TE system can include at least one heat exchanger in thermal communication with and/or physically integrated with the at least one hotter side shunt. The at least one heat exchanger can be substantially electrically isolated from the at least one TE element. In some embodiments, the at least one hotter side shunt is physically coupled with the at least one heat exchanger. In certain embodiments, the at least one heat exchanger is in close physical proximity to the plurality of TE elements, such that cooling power, heating power, or power generation from the TE elements that is lost from ducting and other components that slow warm up or light off is reduced. In some embodiments, the at least one heat exchanger has a honeycomb structure. The TE system can include at least one alternative and/or additional flow path configured to reduce heat transfer between at least one working media and the at least one heat exchanger in certain embodiments.

In certain embodiments, a catalytic converter is provided. The catalytic converter can include one or more of the TE systems. The catalytic converter can also include at least one controller configured to individually control each of the plurality of TE systems, and at least one sensor in communication with the at least one controller and configured to measure at least one operating parameter of the catalytic converter. The at least one controller can adjust electrical power sent to the plurality of thermoelectric systems in response to the at least one operating parameter.

In certain embodiments, a TEG is provided. The TEG can include at least one heat exchanger and at least one combustor integrated into the at least one heat exchanger. The TEG can also include at least one hotter side shunt physically integrated and in thermal communication with the at least one heat exchanger, and at least one cooler side shunt. At least one TE element can be sandwiched between the at least one hotter side shunt and the at least one cooler side shunt, and the at least one heat exchanger can be substantially electrically isolated from the at least one TE element.

In some embodiments, a TEG is incorporated into a motor vehicle, such as, for example, into a truck. In certain such embodiments, the TEG can be configured to run in one or more modes of operation, including, for example, a primary mode of operation and a secondary mode of operation. For example, when in a primary mode, the TEG can convert thermal power to electrical power for use by the truck or driver, or for storage in an electrical energy storage device. A TE device can be located near an exhaust system of the truck and used to convert thermal power in the exhaust system to electrical power. The electrical energy can be used or stored for later use. In some embodiments, the thermal energy can be stored in a thermal energy storage device for later use and/or for later conversion to electrical energy (e.g., using the TE device). In some embodiments, in a primary mode of operation, the TEG may be used as a temperature control device or to supplement electrical power provided by the engine, battery and/or alternator.

When the truck is turned off, or the driver otherwise prefers to not use electrical power provided by the engine, battery and/or alternator, the TEG can enter a secondary mode and provide electrical power to the electronic devices. A burner can use small amounts of fuel from the truck's fuel tanks to generate thermal power in the truck's exhaust system. The TEG located at or near the exhaust system can convert the thermal power generated by the burner to electrical power for use by the electrical devices. Any stored thermal energy can be converted by the TEG and used as desired. Once the stored energy is depleted, the burner can be activated to provide additional thermal energy for the TEG.

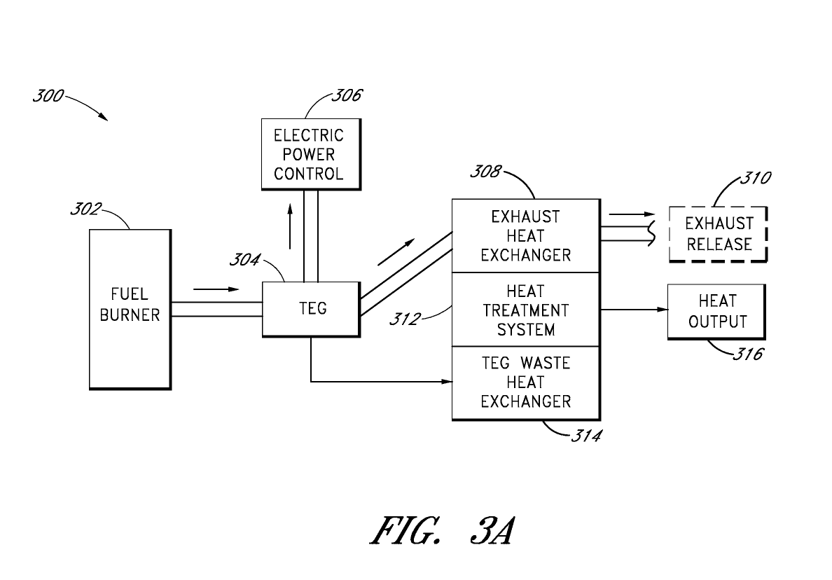

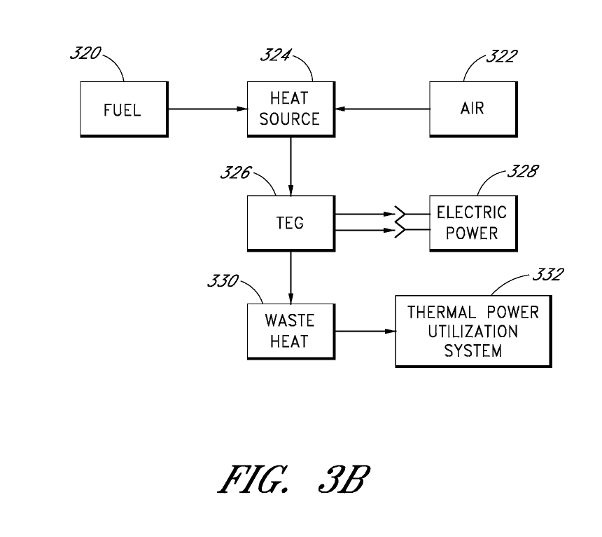

FIG. 3A is a block diagram illustrative of an embodiment of an integrated power system 300 used to generate heat for a particular use, such as for a boiler, hot water heater, residential, commercial and/or industrial furnace or other thermal heater. The integrated power system 300 includes a fuel burner 302, a TEG 304, and electric power control 306, and exhaust heat exchanger 308 and exhaust to air release 310, a heat treatment system 312, a TEG waste heat exchanger 314, and a heat output 316. The integrated power system 300 may be used in conjunction with buildings, vehicles or other devices that use fuel to heat an object. For example, many buildings burn fuel in a boiler, furnace, hot water heater, drying oven, HVAC system. Airplanes will often heat the air and/or fuel before it enters the jet engine or turbine. In such systems, a TEG can be placed in thermal contact with the combustor so that some portion of the heat produced during combustion passes through the TEG thereby producing electrical power. The thermal power not converted to electrical power by the TEG can be used to preheat fuel or air prior to combustion in the engine. In some embodiments, the thermal power not converted by the TEG can be used to heat cabin or interior air or be convected from the TEG to the air outside of the aircraft by a heat exchanger.

The fuel burner 302 can be any number of different burners that combust fuel to generate heat. As an example, the fuel burner may include a fuel injector, an ignition source, a combustion chamber, a combustion product flow channel, a working fluid circuit, a heat exchanger, other burner components, or a combination of burner components. The burners can operate as gravity fed systems powered by coal or oil shale, low pressure buoyancy burners using natural gas or oil, pressurized systems using injected fuel oil, JP8, natural gas or any other burner system. Combustion temperatures can range, for example, from 600° C. to over 1,200° C. The fuel burner can be used in conjunction with a heat exchanger to heat a working medium such as air, oil, gas, liquid metal, and the like. One or more working media can be used to transfer thermal energy to components of the integrated power system 300.

The TEG 304 can be similar to the thermoelectric generators described earlier, and can be used to convert thermal power to electrical power. Because combustion normally occurs at high temperature within the integrated power system 300, the TEG 304 can be used to convert some of the thermal power to generate electrical power. The electrical power can be used to provide power to a number of systems or devices. In some embodiments, when power is lost to the system, the electrical power generated by the TEG 304 can be used to provide emergency power to systems, such as security systems, medical systems, lighting or other emergency systems. The thermal power in the exhaust stream that is not converted to electrical power by the TEG 304, which may be 30% or more, is transmitted to the exhaust heat exchanger 308.

The exhaust heat exchanger 308 transfers the heat to the release 310, or transfers the heat to a heat treatment system 312, such as a boiler, furnace, hot water heater, drying oven, HVAC system, etc. The heat treatment system 312 then provides the heat output 316.

The thermal flux that passes through the TEG 304 and is not converted to electrical energy can be transferred to the TEG waste heat exchanger 314 and on to the heat treatment system 312. Since the efficiency of a TEG is substantially less than 100%, the system 300 can capture most of the heat not passing through the TEG as well as that passing through the TEG but not converted to electrical power.

Under certain conditions, such as electrical power outage in a home, it can be desirable to have an emergency source of electric power, regardless of whether the normal function of the heat treatment system 312 and its output 316 are desired. In such a case, the system 300 may be operated to supply the desired electric power whether or not the primary system function is desired. For example, if a hurricane causes an electric power outage, it may be desired to operate the TEG 304 at a sufficient (possibly reduced) fuel burn rate to provide electric power for security systems, computer power, medical equipment power, emergency lighting, and the like. In such a case, a user may be ambivalent to the use of a furnace heater.

FIG. 3B is a block diagram illustrating an embodiment of the underlying thermodynamic system of FIG. 3A. The thermodynamic system includes fuel 320, an oxidizer 322, a heat source 324, a TEG 326, electrical energy 328, waste heat 330, and a thermal power utilization system 332.

The fuel 320 can be any number of types of fuels as described above. The fuel 320 and an oxidizer (such as air) 322 are transferred to the heat source 324 for combustion. The heat source 324 can be a burner or any other type of combustor that is capable of combusting the fuel and oxidizer, as described above. The heat source 324 generates thermal power (heat) from the combustion of the fuel 320 and the oxidizer 322. The heat is transferred to the TEG 326. The heat can be transferred directly through placing the TEG in good thermal contact with the heat source 324 or via heat exchanges and any number of working media as described above.

The heat produced from the heat source 324 enters the “hot” side of the TEG 326, and the TEG converts a portion of the heat to electrical energy 328. The portion of the heat that is not converted to electrical energy 328 exits at a lower temperature as waste heat 330. The waste heat 330 from the TEG 326 can be used by the thermal power utilization system 332 as described in FIG. 3A. In some embodiments, additional pathways can be added to allow the waste heat from the TEG 326 to preheat the air 322 before it enters the heat source 324. With the addition of the TEG 326, while some of the thermal power of the heat 324 is used by the TEG 326 to generate electrical power 328, the majority of the heat can still be used by the thermal power utilization system 332.

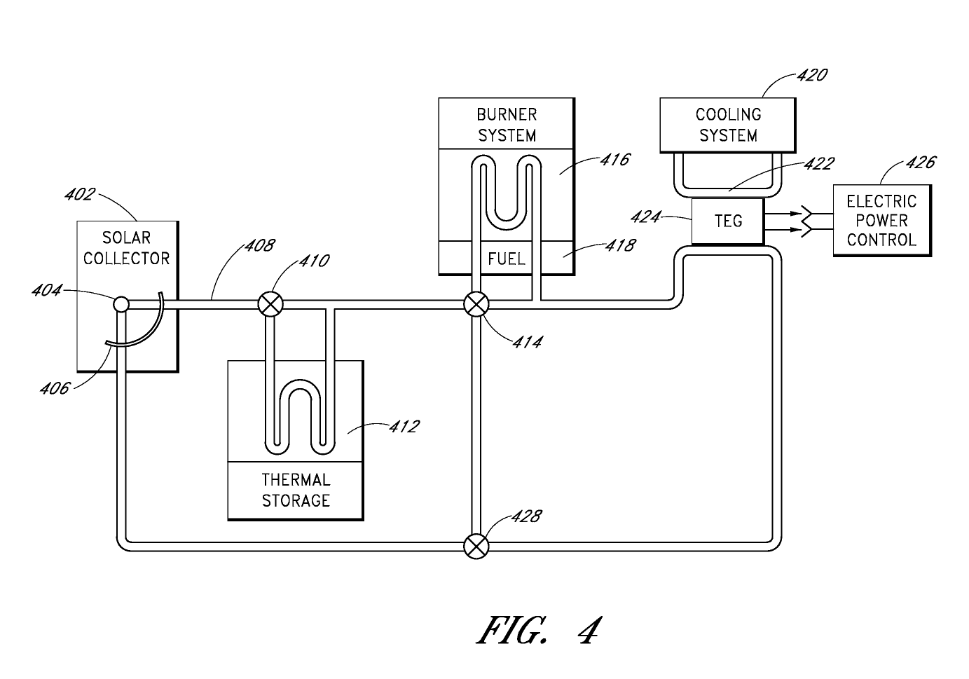

FIG. 4 is a block diagram illustrating an embodiment of a solar-thermal system 400 in which solar power is converted to electric power by a TEG. The solar-thermal system 400 includes a solar collector 402, working medium collector conduit 404, concentrator 406, a conduit 408, junction valves 410, 414, 428, a thermal energy storage device 412, a second heat source 416 with fuel 418, a TEG 420, a cooling system 422, and cooling exchange 424, and an electric power control. In some embodiments, the system 400 is configured to supplement the sun as a source with heat from a second heat source 416, such as, for example, a burner and/or thermal storage 412, as solar power varies with time. In certain embodiments, the system 400 can operate in the night, during inclement weather, and when additional electric power is demanded, whether during the day or during the night.

The system 400 collects solar power in the solar collector 402. The solar collector 402 can be implemented using any number of designs including flat plate collectors, evacuated tube collectors, parabolic trough, parabolic dishes, etc. A concentrator 406 forming part of the solar collector or in close proximity to the solar collector can be used to concentrate the solar power to increase the heat flux and the temperature achieved by heating a working medium (e.g., molten metal, molten salt, super-heated water, oil, anti-freeze, or other liquid, hot pressurized gas, or any other suitable working medium) in the conduit 404. The concentrator 406 can be complemented using a mirror, lens or other device.

The conduit 404 forms the transportation mechanism for working medium within the system 400, and can be implemented using one or more flow channels, heat exchangers, valves, manifolds, blend doors, other conduit components, or a combination of components. The conduit 404 forms one or more pathways for moving thermal power between the solar collector 402, the thermal storage 412, the second heat source 416, and TEG 420. The conduit 404 can provide a feedback loop and/or circuit path that allows the working medium to return to the solar collector to be reheated.

The thermal storage 412 can be used to store the thermal energy captured by the solar collector 402 for later use. The thermal storage can store the thermal energy using molten salt, water, a phase change material, another thermal energy storage medium, or a combination of thermal energy storage media. In some embodiments, the thermal storage system 412 can store sufficient thermal energy to provide nominal electric power output by the TEG 424 for greater than or equal to about 12 hours and/or less than or equal to about 24 hours. Economic, size, weight, weather or other conditions can be used to determine the desired amount of storage capacity. In certain embodiments, the storage temperature is greater than or equal to the nominal TEG 424 inlet temperature.

The second heat source 416 can heat the working medium to a higher temperature than may be available from the solar collector 402 and/or the thermal storage system 412. Thus, if electric demand increases and the TEG 420 can operate to produce more electric power at higher temperatures, the heat source 416 can supplement the solar collector 402 to meet the increased demand. In addition, if the combination of the solar collector 402 and the thermal storage system 412 does not meet normal demand, the heat source 416 can add thermal power to the working medium in order to boost power generation. In some embodiments, the amount of boosted power generation produced by the heat source 416 substantially reduces or eliminates any power generation shortfall.

The energy management system can include one or more junction valves 410, 414, 428 to control the flow of the working medium. A thermal storage junction valve 410 is used to direct the heated working medium through and/or around the thermal storage system 412. For example, in certain embodiments, the junction valve 410 can apportion the working medium flow so that a portion of the thermal energy is stored in the thermal storage system 412 and the portion used to provide electrical power to a user bypasses the thermal storage system 412. When too little or no thermal power is being produced by the solar collector 402, the junction valve 410 can adjust the apportionment between the thermal storage system 412 and the bypass such that, for example, a greater portion or all of the working medium flows through the thermal storage system 412. In some embodiments, the working medium is heated to a temperature of greater than or equal to about 300° C. An efficient operating temperature can be determined by an analysis of the thermal loss mechanisms which generally increase with operating temperature, including radiative, conductive and convective losses within the system, the possible higher cost of TEG 424 materials for operation at higher temperatures and other factors and the potential efficiency gains from operating the TEG 424 at higher temperatures, the possibility of higher capacity at higher temperatures and other factors. Normally, these factors would be incorporated into a computer model of the system to predict the operating temperatures, working medium properties and flow rates, output voltages, output power and other characteristics. The results can be used with economic models to determine appropriate operating conditions, materials, and other design information.

An auxiliary heater junction valve 414 can direct the working medium to a second heat source 416, such as a burner system, powered by combustion of a fuel 418, or to the TEG 424 to be converted to electrical energy. Similar to the thermal storage junction valve 410, the auxiliary heater junction valve 414 can apportion the working medium between the heat source 416 and the TEG 424 as desired.

The bypass junction valve 428 can be used in combination with the auxiliary heater junction valve 414 to redirect the working medium flow when the solar collector 402 does not heat the working medium adequately. For example, during the night when the solar collector 402 is unable to heat the working medium and the thermal energy in the thermal storage 412 is depleted, the bypass junction valve 428 can conserve thermal energy by opening the pathway that bypasses the solar collector 402 and the thermal storage 412. Accordingly, the working medium flow bypasses the solar collector 402 and the thermal storage 412 to be reheated by the heat source 416 and then directed back to the TEG 424.

Based on the configuration of the junction valves 410, 414, 428, the working medium can provide the thermal power to the “hot” side of the TEG 420. A cooling source 422 is connected to a cooling system 424. The cooling system 424 cools the “cold” side of the TEG 420. Electrical power produced by the TEG 420 flows to an electric power control 426 for use.

Although not illustrated, an electronic control unit uses input sensors (e.g., temperature sensors, flow rate sensors, speed sensors, solar flux measurements, pressure sensors, voltage sensors, current sensors, operating condition data, safety systems, readiness sensors, etc.) to operate the system 400 and control the junction valves, pumps (not shown), fans (not shown), safety devices (not shown), etc., to determine available capacity, output rates, total output, and the like.

In addition, although illustrated as a solar-thermal system, a number of alternative and/or additional systems can be used. For example, the solar collector 302 can be replaced with a coal burner, gas burner, geothermal energy source, engine, battery, solid oxide fuel cell, furnaces, pyrometalurgical systems or other energy sources that produce heat.

Renewable power sources are frequently used to supply electrical power to users. However, whenever the renewable power source is not present, such as, for example, when the sun is obstructed, when there is no wind, etc., the infrastructure to generate electricity (converters, wiring, and other equipment) sits idle, and electrical power is not generated. Further, the power supplied by many renewable power sources fluctuates according to environmental conditions beyond the control of the power source. This fluctuating nature prevents the use of renewable energy sources as the primary means of generating power for many industries and persons that require an uninterrupted flow of power.

For example, solar arrays convert solar radiation received from the sun into electrical power. However, when the sun is not shining or when an object, such as a cloud, is obstructing the sunlight from reaching the solar panels, the solar panels are unable to generate power. Similarly, a wind farm uses wind power to generate electricity. However, if there is insufficient wind to turn the turbines, a windmill is unable to generate electricity. Thus, the amount of power generated by a renewable power source fluctuates over time due to their reliance on nature.

In addition, renewable power generation systems lack infrastructure to efficiently monitor the use of the electrical power produced. Current systems provide electrical output to a site. If excess power exists beyond the demands of the site, the system sends power to a local grid without an integrated understanding of the value of a kWh of electrical power to the grid at a particular moment, or a way to adjust usage accordingly.

Systems for supplying energy from renewable sources (such as wind power or solar power) or non-renewable sources can have various drawbacks, including the inability to supply a constant flow of power due to the reliance on nature. For example, solar panels function better with direct access to sunlight, wind farms function well under windy conditions, wave farms function best with substantial waves, and so forth. Even non-renewable power sources can be unreliable, especially if the power is transmitted over long distances to users. In addition, these systems typically do not reuse the electrical power produced. For example, the electrical power supplied to a user is often converted at least partially into thermal energy during use. The systems producing the electrical power may be unable to make use of generated heat, which can be lost as waste heat. As such, much inefficiency may exist.

Further, many renewable systems can provide electrical power back to the local electrical grid. The grid is usually tied into a renewable system as a back-up in case of failure. However, these systems do not control when and in what quantities the excess renewable power is sold back to the local grid, resulting in inefficiencies on both ends. The owner of the renewable system is unable to sell the power produced by his or her system at a time of high demand (and high price), and the local grid may be unable to predict when additional energy will be available. In some embodiments, a system is configured to selectively provide electrical power from a TEG to a user, device, or grid according to whichever has the greatest demand.

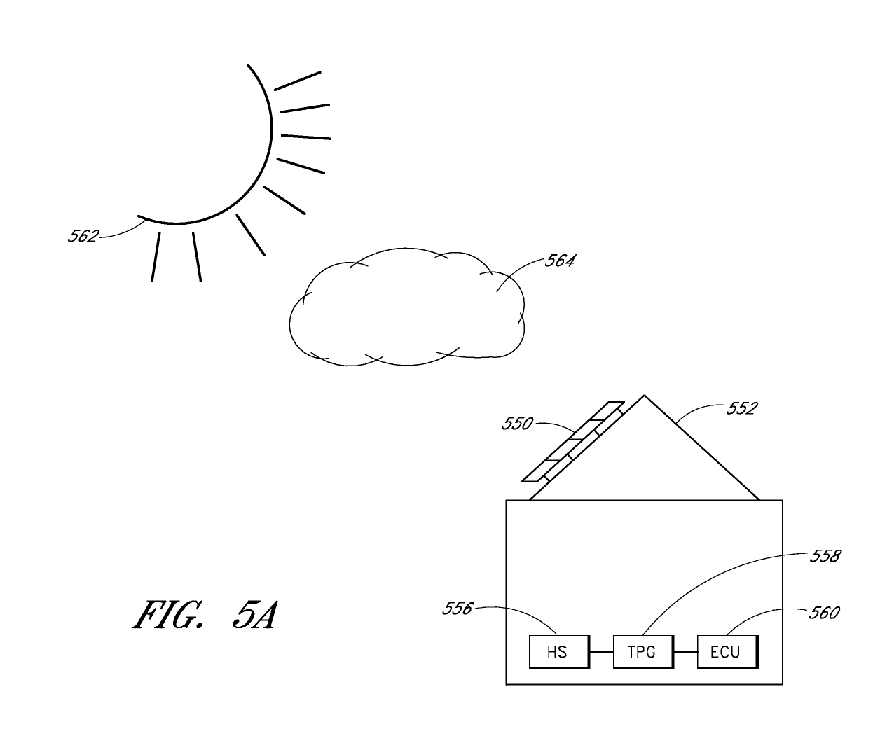

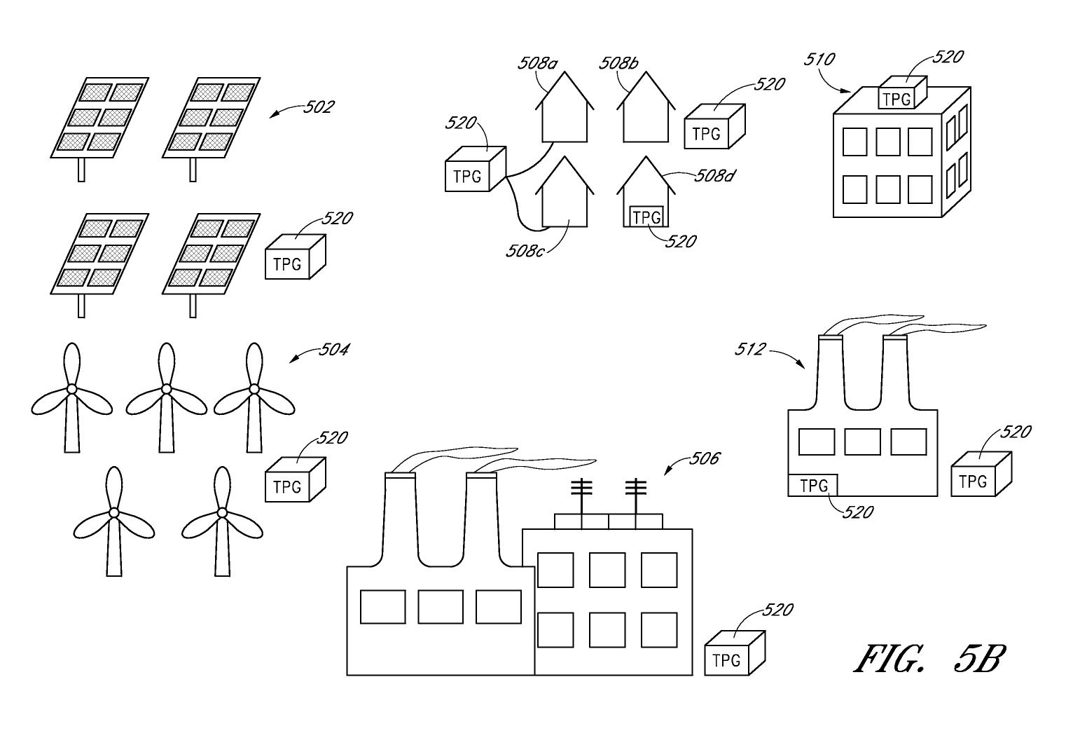

FIG. 5A is a block diagram illustrative of an embodiment of an integrated power system including a PPS 550, a PPU 552, a heat source (HS) 552, a TEG 558, which can include energy storage devices, and an electronic controller unit (ECU) 560. As illustrated in FIG. 1, a power source 562 provides power to the PPS 550, which converts the power into electrical power, for use by the PPU 552. In addition to the PPS 550, the TEG 558 can also provide electrical power to the PPU 552. The ECU 560 monitors the PPS 550 to determine if electrical power from the TEG 558 should be used.

In some embodiments, the PPS 550 converts power received from the power source 562 into electrical power to be used by the PPU 552. In the embodiment illustrated in FIG. 1A, the power source 562 is a renewable power source (solar power), and the PPS 550 is a solar array. As will be discussed in greater detail below, with reference to FIGS. 1B, the power source 562 may be any number of renewable power sources such as solar power, wind power, geothermal power, tidal power, wave power, and the like, or non-renewable power sources, such as nuclear fossil fuels including coal, gas, natural gas, petroleum, and the like. Similarly, the PPS 550 may be any number of different systems that can generate power from renewable and non-renewable power sources. Furthermore, the PPS 550 may be located in close proximity to the primary power user 552. For example, as illustrated the PPS 550 is connected to the PPU 552. In some embodiments, when in close proximity, the PPS 550 can be detached from the PPU 552. For example, the PPS 550 can be within a few hundred feet or miles of the PPU 552. In another embodiment, the PPS 550 is located remotely from the PPU 552. For example the PPS 550 can be located in or at a power plant that is located a few miles, hundreds of miles, or even thousands of miles away from the PPU 552.

The primary power user (PPU) 552 may be any type of entity that requires electrical power. For example, the PPU 552 can be a home, commercial building, office building, factory, industrial complex, vehicle, or the like. Although illustrated as a single user, the PPU 552 may be a number of different users receiving electrical power from the same PPS 550.

The IPS also includes a heat source (HS) 556, and a TEG 558 in close proximity to the HS 556. In some embodiments, the TEG 558 is thermally coupled with the HS 556. The HS 556 may be any number of appliances or devices that generates sufficient heat to be used by TEG 558 to generate electrical power. For example, the HS 556 can be a home appliance, business appliance, industrial machine, a burner, or the like. In addition, the HS 556 can be naturally occurring, such as a building rooftop, the ground, ambient air, a geothermal phenomenon or the like. The HS 556 can be located in close proximity to the primary power user 552 or the PPS 550. In some embodiments, the HS 556 is the PPS 550.

In some embodiment, the TEG 558 includes one or more storage devices. The one or more storage devices can include, for example, thermal energy storage devices, which store thermal energy that can be converted into electrical power by the TEG 558, and electrical storage devices, which store the electrical power generated by the TEG 558. In addition, the storage devices may be located in close proximity to, such as connected to or within a few feet or miles, or remotely, such as several miles or even hundreds or thousands of miles, from the TEG 558.

The IPS also includes an electronic controller unit (ECU) 560. The ECU 560 monitors the TEG 558 and the PPS 550. In some embodiments, the ECU 560 communicates with the TEG 558 and the PPS 550 using a power distribution protocol. The power distribution protocol can include power usage factors, criterion, one or more rules, algorithms, heuristics, artificial intelligence, sets of instructions, and the like to determine the appropriate actions of the ECU 560. In one embodiment, the power distribution protocol provides one or more power usage factors for determining how to allocate electrical power to the PPU 552. In one embodiment, the one or more power usage factors includes threshold power and energy levels, expected weather patterns, power levels of storage devices, time of day and/or year, and the like.

With continued reference to FIG. 5A, using the power distribution protocol, the ECU 560 can communicate with and operatively connect the TEG 558 with primary power user 552 to supply power upon detecting that the PPS 550 is supplying electrical power to the PPU 552 below a threshold power level. Thus, if the ECU 560 detects that the PPS 550 is supplying electrical power below a threshold power level, or if the ECU 560 detects that the electrical power output of the PPS 550 has dropped, the ECU 560 can communicate with the TEG 558 and operatively connect the TEG 558 with power user 552 to supply additional electrical power. The threshold power level can be determined based on previous power levels, expected power levels, or current demand by the PPU 552. As mentioned previously, other power usage factors or rules may be used, such as expected weather patterns, energy levels of storage devices, time of day and/or year, and the like.

Once the ECU 560 detects that the power output of the PPS 550 has returned to normal, or is at or above the threshold power level, the ECU 560 can communicate with the TEG 558 and operatively disconnect the TEG 558 from the PPU 552. As will be described in greater detail below, the ECU 560 can also determine if one or more energy storage devices can be charged, or if excess power generated by the PPS 550, or the TEG 558, should be sent to the local grid. The ECU 560 can be implemented using a microcontroller, personal computer, server, other computing device, or the like. Furthermore, in an embodiment, the ECU 560 is located at or in close proximity to the PPU 552. For example, if the PPU 552 is a residential, commercial or industrial building, the ECU 560 may be located within the building. In another embodiment, the ECU 560 is located in close proximity to the PPS 550. For example, the ECU 560 can be integrated with the power source, located within a power station or in a nearby controller near the power source or station. In yet another embodiment, the ECU 560 is located remotely from both the PPU 552 and the PPS 550. For example, the ECU 560 can be located in a control station located hundreds or even thousands of miles away from both the PPU 552 and the PPS 550. In such an embodiment, the ECU 560 can communicate with the PPU 552 and the PPS 550 via the internet, fax, telephone or other long distance mode of communication. In one embodiment, one or both of the PPS 550 and the PPU 552 contain an ECU 560, which can communicate with the other components and control the individual component.

As an example and not to be construed as limiting, the power source can be solar power 562 from the sun, the PPS 550 can be a solar array, the PPU 552 can be a residential unit, and the HS 556 can be a home appliance such as an oven, refrigerator, furnace, or other appliance that generates waste heat. In some embodiments, the HS 556 can be the roof of the residential unit.

In this example, the ECU 560 monitors the power output of solar array 550. The TEG 558 is thermally coupled to the HS 556 and is capable of storing at least some of the heat generated by the HS 556. In addition, the TEG 558 can operate a primary mode and a secondary mode. While in the primary mode, the TEG 558 can act as an auxiliary power source for the residential unit. The TEG 558 can convert the waste heat (thermal power) produced by HS 556 to electrical power, store the thermal power from the HS 556 for later conversion to electrical power, convert the thermal power to electrical power, store the converted electrical power, and/or supply the converted electrical power to a local power grid. When the power output of solar array 550 is stable or supplies enough power to meet the demands of the residential unit, the TEG 558 can continue to store the thermal and electrical energy and/or provide the converted electrical power to the local power grid. When the solar array is activated, but the power output of the solar array is insufficient to meet the demands of the residential unit, the TEG 558 can act as an auxiliary power source for the residential unit and supplement the electrical power from the solar array.

For example, if a cloud 564 or other obstruction impedes solar power 562 from reaching the solar array, or there is a spike in power usage, the ECU 560 can detect that demand exceeds supply and can operatively connect the TEG 558 to residential unit as an auxiliary power source. The TEG 558 can supply electrical power to the residential unit, to supplement the power provided by the solar array. Once the ECU 560 detects that the power output of solar array 550 has returned to normal, or that the solar array 550 is capable of supplying sufficient power for the PPU 552, the ECU 560 operatively disconnects the TEG 558, and the TEG 558 resumes collecting and storing thermal energy from the HS 556, converting the thermal power to electrical power and/or storing the electrical energy or supplying the electrical power to the local grid.

In the secondary mode, the TEG 558 can operate as the primary power source for the residential unit. For example, a solar array may be unable to generate electricity at night, may be disconnected from the residential unit, or may malfunction during the day and be unable to provide electricity to the residential unit. To generate electricity for the residential unit, the ECU 560 can cause fuel to be supplied to the HS 556 to generate thermal power. For example, if the HS 556 is an oven, furnace, or a burner, the ECU 560 can activate the oven, furnace or burner to generate heat. Using the same waste heat recovery process as in the primary mode, the TEG 558 can convert the thermal power from the HS 556 into electric power for use by the residential unit. Thus, the TEG 558 can become the primary power source for the residential unit when the PPS 550 can not be used.

FIG. 5B is a block diagram illustrative of another embodiment of the IPS. As part of the IPS, FIG. 5B illustrates the PPS 502, 504, 506 supplying power to a number of different PPU 508a-508d, 550, 512. The IPS further includes one ore more thermoelectric power generator systems (TEG) 520, which may be located in close proximity to the PPS 502, 504, 506 or the PPU 508, 550, 512. Although not illustrated in FIG. 5B, heat sources similar to the HS 56 of FIG. 5A are located in close proximity to TEG 520. In addition, an ECU, similar to the ECU 560 of FIG. 5A can be located in a variety of different locations, including in close proximity, e.g. connected to or within a few feet or miles, or remotely, e.g. several miles, hundreds or thousands of miles, from the PPS 502, 504, 506 or the PPU 508, 550, 512. Additionally, the ECU may be located remotely, as mentioned previously, from both the PPS 502, 504, 506 and the PPU. The various elements of the IPS will now be described in greater detail.

As illustrated in FIG. 5B, the PPU may include residential users, commercial users, industrial users, vehicles, and the like. The IPS includes at least one TEG 520. However, as illustrated, multiple TEGs 520 may be used. The TEG 520 may be located in close proximity to the power source or it may be located in close proximity to the users.

Although not illustrated in FIG. 5B, TEG 520 can include energy storage devices. In another embodiment, the energy storage devices are separate from the TEG 520. The energy storage devices can include thermal energy storage devices capable of storing thermal energy that can be converted to electrical energy by the thermoelectric device. In certain embodiments, the energy storage devices include electrical energy storage devices capable of storing the electrical energy converted by the TEG 520.

The TEG 520 is thermally coupled to a heat source, and can be placed in a variety of locations. For example, the TEG 520 may be located in proximity to one or both of the PPS 502, 504, 506 and the PPU. In some embodiments, the TEG 520 may be located remotely, e.g. from a few miles to hundreds or thousands of miles, from one or both of the PPS 502, 504, 506 and the PPU. As illustrated in FIG. 5B, the IPS may include multiple TEGs 520. Each PPU may have one or more TEGs 520, such as the PPU 512, or multiple PPU may share a TEG 520, such as the PPU 508a and 508c. The TEG 520 can be located inside or outside a building. The heat source can be the heat generated from a machine, engine, burner, manufacturing facility, etc., or can be naturally occurring, such as the roof of a building, the ground, ambient air, or geothermal activity. In addition, the TEG 520 can act as an auxiliary power source in a primary mode and act as a primary power source in a secondary mode.

As an example of the primary mode, when enough sunlight is shining, the solar array 502 can supply sufficient power for PPU 508, 510, 512. However, when there is insufficient light such as in the case of a cloudy day, eclipse or the like, or when the PPUs 508, 510, 512 demand more power than the solar array 502 is capable of producing, the solar array 502 may be unable to supply sufficient power for PPU 508, 510, 512. In some cases, a cloud or other object may obstruct the solar array or there may be a spike in power use by the PPU 508, 510, 512, both of which can lead to insufficient power. In such a scenario, the TEG 520 can provide energy to supplement the power output of the primary power source.

When the solar array 502 is supplying sufficient power for power users 508, 510, 512, the TEG 520 can store energy or provide it to a power grid. When demand exceeds supply the solar array 502 is unable to maintain its power output, an ECU operatively connects TEG 520 to supply the difference in power to the PPU 508, 510, 512. In another embodiment, when the solar array 502 produces more power than is demanded by the PPU 508, 510, 512, the excess power can be stored in a storage unit. The storage unit can be either a thermal energy storage unit or an electrical energy storage unit. When the solar array 502 is unable to supply sufficient power to the PPU 508, 510, 512, the ECU can transfer the power stored in the storage unit along with the power generated by the TEG 520 to replace the difference of power that is no longer supplied by the solar array. In other embodiments, the TEG 520 can supply power to auxiliary power users, or an electrical infrastructure, such as a local grid. If additional electrical power is demanded, a burner can provide additional heat to the TEG 520.

As another example of the primary mode, when there is sufficient wind, wind farm 504 can supply power to the PPU 508, 510, 512. However, when there is insufficient wind, the power supplied from wind farm 504 can drop precipitously. In such a scenario, TEG 520 can provided power to replace the loss in power supplied from wind farm 504. Similar results can be achieved when using other renewable power sources, such as wave farms, tidal farms, geothermal power plants, and the like. In some instances, even when sufficient power is being generated from a renewable or non-renewable power source, reliability issues in the grid prevent sufficient power from reaching the PPU 508, 510, 512. Thus, even when a fossil-fuel power plant 506, or other power source, generates sufficient power, the PPU 508, 510, 512 may require more than what is received. In such a scenario, TEG 520 can provide power to meet the demands of the PPU 508, 510, 512. Once the reliability issues have been resolved, TEG 520 can return to storing and converting the thermal energy from a heat source. In other instances, the PPU 508, 510, 512 simply demand more power than a primary power source is capable of supplying. The TEG 520 can be used to supplement power in these instances as well, when in a primary mode.

In a secondary mode, the TEG 520 can be used as the primary power source for the PPU 508, 510, 512. For example, the TEG 520 can be used as the primary power source at night to complement the solar array 502 that is unable to provide electricity at night. In certain embodiments, the TEG 520 can be used as the primary power source to complement the wind farm 504 when there is no wind. In addition, the TEG 520 can be used as the primary power source when a power station or power lines are under repair, when a vehicle engine is off, or at any other time when one or more PPUs 508, 510, 512 prefer not to use a PPS 502, 504, 506.

Upon entering the secondary mode, the TEG 520 can use its heat waste recovery process to generate the electricity desired by the PPU 508, 510, 512. If a heat source is not producing sufficient thermal power for the TEG 520, the ECU can cause fuel to be provided to the heat source to increase the amount of thermal power being generated. For example, the ECU can activate a burner and supply enough fuel to the burner to produce sufficient thermal power for the TEG 520.

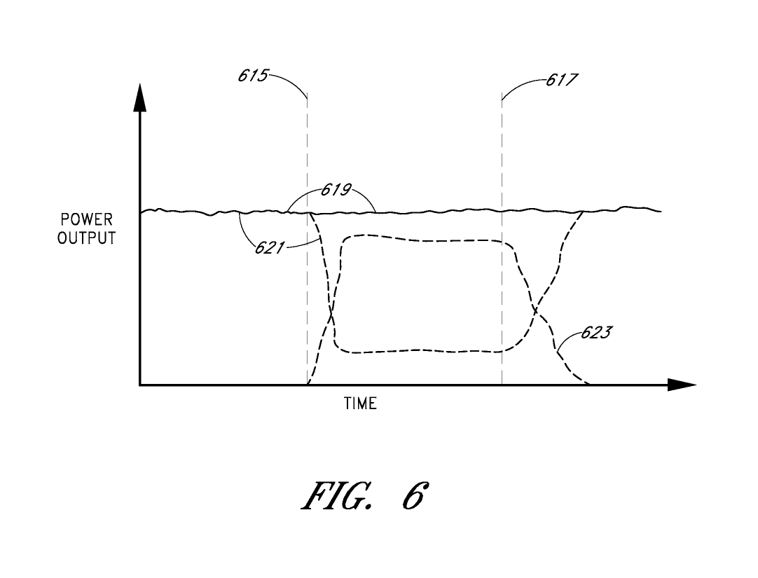

FIG. 6 is a graphical representation illustrative of an example of the power output 619 of an IPS, including the PPS power output 621, and the TEG power output 623 when the TEG is operating in a primary mode (auxiliary power source). The graphical representation charts the power output 619 of the IPS on the y-axis against time on the x-axis. As illustrated, initially the IPS power output 619 and the PPS power output 621 is essentially the same and is relatively constant until an event occurs at time 615. The event may represent any number of occurrences including cloud cover, light obstruction, lack of wind, fluctuating geothermal power, tidal or wave changes, reduction in power at a non-renewable power plant, transmission line issues, or the like. At time 615, the PPS power output 621 begins to drop precipitously. Upon detecting the drop in the PPS power output 621, the ECU is able to communicate with and operatively connect the TEG with the PPU to provide auxiliary power. The TEG power output 623 is able to replace the decrease in the PPS power output 621. Thus, the IPS power output 619 is able to remain relatively stable throughout the event. As the PPS power output 621 varies, the ECU 560 is able to alter the TEG power output 623 to ensure the proper levels of power output for the IPS. Once the event ends at time 617 and the PPS power output 621 is able to return to normal levels, the ECU can operatively disconnect the TEG from the PPU. The TEG can return to storing energy from the HS 56.

In some embodiments, the ECU monitors the power demands of the PPU and the auxiliary power users (APU) in addition to the power output of the PPS. In the event that the power demands by the PPU and the APU exceed the power output of the PPS, the ECU operatively connects the TEG to the PPU and/or the APU to supply the additional power demanded. Power demands by the PPU and the APU may exceed the power output of the PPS for any number of reasons including an increase in power demand due to an increase in electrical energy use by the PPU and the APU, a decrease in power output of the PPS, or both. By monitoring the power demands of the PPU and the APU and the power output of the PPS, the ECU is able to more readily supply a sufficient amount of power from IPS for use by the PPU and the APU.

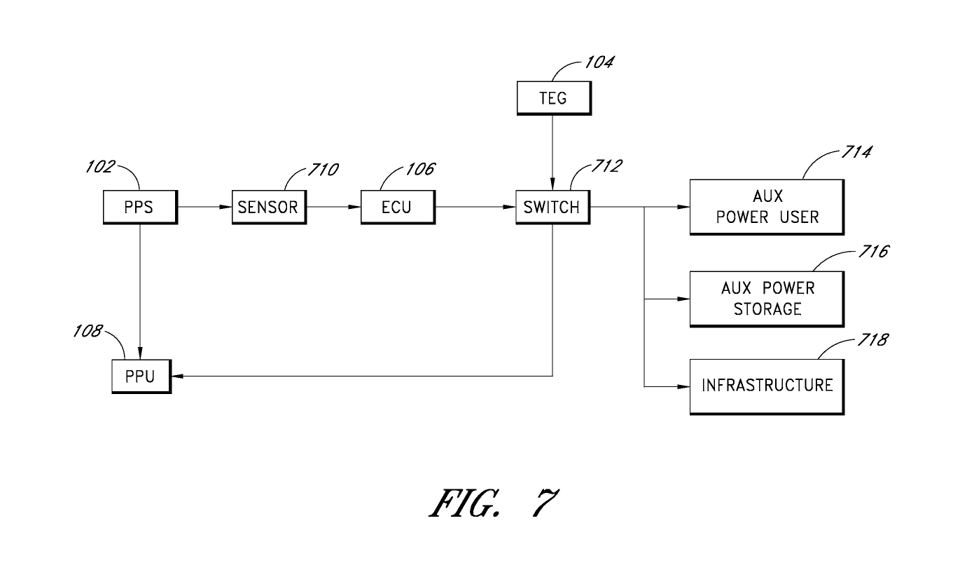

FIG. 7 is a schematic diagram of another embodiment of an IPS, including a PPS 102, a TEG 104, an ECU 106, one or more PPUs 108, one or more sensors 710, one or more switches 712, one or more auxiliary power users (APUs) 714, one or more auxiliary storage devices (ASDs) 716, and a power distribution infrastructure (PDI) 718. The embodiment shown in FIG. 7 can be similar in many respects to the embodiment illustrated in FIG. 1. For example, the various components may be in direct communication with one another and/or may communicate via the ECU 106. In some embodiments, one or more sensors 710 are in communication with the PPS 102 and the ECU 106. In some embodiments, one or more switches 712 are in communication with the ECU 106.

The PPS 102, the TEG 104, and the ECU 106 function in a similar capacity to those described above with reference to FIG. 1. However, the embodiment illustrated in FIG. 7 differs from the embodiment illustrated in FIG. 1 in at least one regard in that sensor 710 and switch 712 are shown as individual components. In other embodiments, one or both of sensor 710 and switch 712 are included within the PPS 102, TEG 104, and/or the ECU 106.

As described above, the PPS 102 generates and transfers power to the PPU 108. Sensor 710 measures the power output of the PPS 102. Sensor 710 may be implemented using any number of sensors as is well known in the art. For example, sensor 710 may be implemented using an electromechanical meter, voltage meter, electrochemical meter or the like. Sensor 710 is also capable of notifying the ECU 106 if the power output drops below a threshold power level.

Upon receiving the notification that the power output of the ECU 106 has dropped below a threshold power level, the ECU 106 actuates switch 712 to operatively connect the TEG 104 to the primary power user 108. The TEG 104 provides power to the PPU 108 to replace the decrease in power output by the PPS 102. In another embodiment, the ECU 106 actuates switch 712 to operatively connect the TEG 104 to the APU 714, an ASD 716, or the PDI 718. In some embodiments, the threshold power level for actuating the switch to connect the TEG 712 to the PPU 108, the APU 714, the ASD 716, or the PDI 718 may be predetermined using previous data or may be determined dynamically based on current power demand. Similarly, other power usage factors may be predetermined or may be determined dynamically using various criteria, algorithms, heuristics, artificial intelligence models, sets of instructions, and the like.

The APU 714 may be similar to the PPU 108 in many respects. The ASD 716 can be a thermal storage device capable of storing thermal energy generated by a heat source or an electrical storage device capable of storing electrical energy generated by the TEG 104. The PDI 718 can be the local power grid.

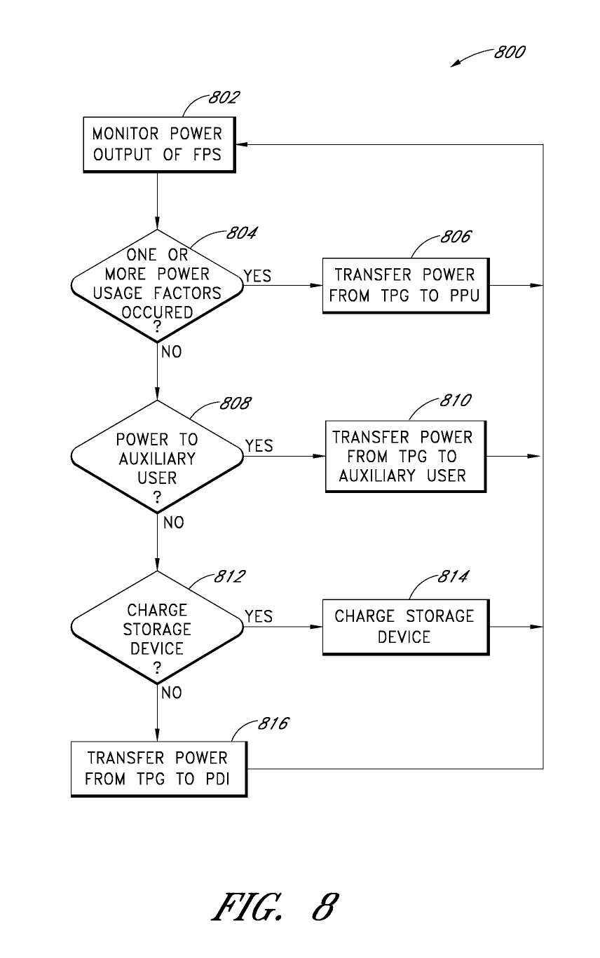

FIG. 8 is a flow diagram illustrative of a routine 800 implemented by an ECU for controlling the allocation of power generated by a TEG. One skilled in the relevant art will appreciate that the elements outlined for routine 800 may be implemented by one or many computing devices/components that are associated with the ECU.

At block 802, the ECU monitors the power output of the primary power supply (PPS). The monitoring may occur at a location in close proximity to either the PPS or the power user. In certain embodiments, the monitoring may occur at a location remote from both the PPS and the power user, as discussed previously. The monitoring may be implemented using a sensor in communication with the electronic controller unit, as described above with reference to FIG. 7, or may occur internal to the electronic controller unit.

At block 804, the electronic controller unit determines if one or more power usage factors have occurred. In some embodiments, one power usage factor includes whether the power output levels of a primary power source (PPS) are falling below a threshold power level similar to that described above with reference to FIGS. 1, 4, and 5A-5B. However, other power usage factors may be used as discussed previously and in more detail below. As discussed earlier, the threshold power level may be predetermined, using, for example, an average or expected power output, or may be determined dynamically based on the demands of PPU, APU, PDI, or other information based on various criteria, algorithms, heuristics, artificial intelligence, models, sets of instructions, or the like. If the ECU determines that the power output is below the threshold power level, the electronic controller unit causes power from the TEG to be transferred to the PPU, as illustrated in block 806. In some embodiments, the aggregate of the power from the TEG and the power from the PPS is greater than the threshold power level. In some embodiments, an additional power source is connected to the integrated system that can also be used in the case where the aggregate of the power from the TEG and the PPS is not greater than the threshold power level. In some embodiments, a burner is used to provide additional thermal power that can be converted to electrical power by the TEG. In some embodiments, the TEG is located in close proximity to the PPS. In another embodiment, the TEG is located in close proximity to the power user. Upon transferring power from TEG to the power user, the electronic controller unit continues to monitor the one or more power usage factors, as illustrated in block 802.

If the ECU determines that the output of the PPS is not less than the threshold power level, the routine moves to determination block 808. At determination block 808, the ECU determines if an APU demands additional power. In some embodiments, the same PPS as the PPU provides power to the APU. In another embodiment, another power source provides the APU with power. If the ECU determines that the APU demands additional power, the ECU causes power from the TEG to be transferred to the APU, as illustrated in block 810. In some embodiments, excess energy generated by the PPS is also used to provide power to the auxiliary power user. In some embodiments, the TEG is located in close proximity to the PPU or the APU. In another embodiment, the TEG is located in close proximity to both the PPU and the APU. In another embodiment, the TEG is located remotely from one or both of the PPU and the APU, as discussed earlier. In one embodiment, the TEG includes multiple TEGs located in different locations and controlled by the same ECU. Upon transferring power to the APU, the ECU continues to monitor the one or more power usage factors, as illustrated in block 802.

If the ECU determines that power is not to be transferred to the APU, routine 800 moves to block 812 and the ECU determines if a storage device should be charged. If the ECU determines that the storage device should be charged, the routine moves to block 814 and the ECU causes the storage device to be charged. As described previously, the storage device can be a thermal storage device, capable of storing and supplying thermal power to the TEG to generate electrical power, or the storage device can be an electrical energy storage device which stores electrical energy generated by the TEG. The storage device can be located in close proximity to or remotely from the TEG, as discussed earlier. In some embodiments, excess power from the PPS is also used to charge the storage device. The TEG can convert excess electrical energy to temperature gradients and a thermal storage unit can store some of the thermal energy generated. When electrical power is demanded, the TEG can be configured convert the stored thermal energy into electrical power. The ECU continues to monitor the one or more power usage factors as the storage device charges, as illustrated in block 802.

If the ECU determines that the storage device should not be charged, the ECU causes the power generated by TEG to be supplied to a power distribution infrastructure (PDI), such as a local grid, as illustrated in block 816. In some embodiments, the power generated by TEG is automatically supplied to the PDI upon determining that the storage device should not be charged. In another embodiment, the ECU determines if power should be supplied to the PDI from the TEG before supplying any power. In some embodiments, the excess power from the PPS can also be transferred to the PDI. Upon transferring power to the electrical infrastructure, the ECU continues to monitor the one or more power usage factors, as illustrated in block 802.

Although not illustrated in FIG. 8, additional steps can be used to determine when to transmit power to the APU, storage device, and the PDI. Additional criteria may include, but is not limited to, a power user's action or inaction, current price of electricity sold back to the local grid, current electricity usage by the PPU and the APU, storage capacity, upcoming demand by the PPU, the APU, or the local grid, time of day, weather conditions, and future electricity production/demand estimates.

Furthermore, it is to be understood that the order of the determination blocks may be changed without affecting the nature or scope of the description. Furthermore, the ECU may make any one or more of the determinations simultaneously or in any order, and may continuously monitor power output of the PPS while performing the additional functions mentioned above.

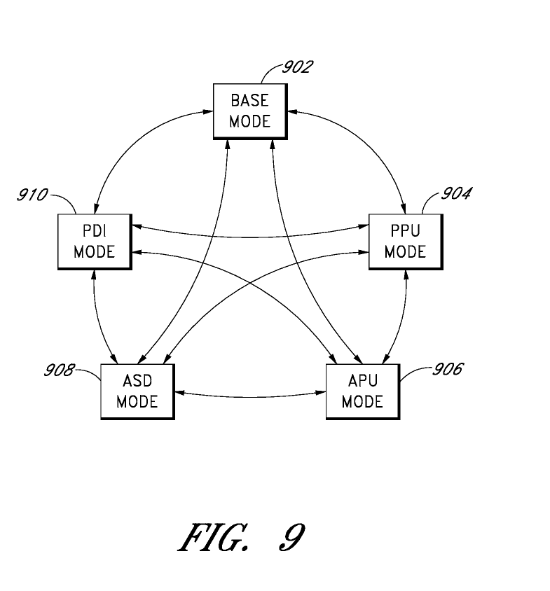

FIG. 9 is a block diagram illustrative of various modes in which the IPS can operate, similar to the flow diagram described above, with reference to FIG. 8. The various modes may include a base mode 902, a primary power user (PPU) mode 904, an auxiliary power user (APU) mode 906, an auxiliary storage device (ASD) mode 908, and a power distribution infrastructure (PDI) mode 910. Additional modes may be added without departing from the spirit and scope of the description. Furthermore, an ECU can monitor the current mode and determine if the mode should be changed based on various criteria. The criteria can include, but is not limited to, user action or inaction, current price of electricity sold back to the local grid, current electricity usage by the PPU and the APU, storage capacity, upcoming demand by the PPU, the APU, or the local grid, time of day, weather conditions, and future electricity production estimates.

In one embodiment, the IPS initially operates within a base mode 902, in which the PPS provides electrical power to a plurality of primary power users. The system continues to operate in the base mode 902 until one or more criteria are met.

If certain criteria are met, the IPS can enter the PPU mode 904. In some embodiments, the IPS enters the PPU mode 904 when the amount of electrical power produced by the PPS falls below a threshold power level. In one embodiment, the threshold power level is predetermined. In another embodiment, the threshold power level is dynamically determined based on current power requirements by the PPU and the APU, or other features as discussed previously. Thus, in an embodiment, the IPS enters the PPU mode 904 when the amount of power demanded by the PPU and/or the APU exceeds the amount of power supplied by the PPS. In one embodiment, when in the PPU mode 904, the system allows electrical power to be supplied by the TEG to the PPU. The system operates in the PPU mode 904 until one or more criteria are met, for example, once the power supplied by the PPS meets or exceeds demands by the PPU and the APU.

In some embodiments, the IPS enters an APU mode 906 when the amount of electrical power produced by the primary power source falls below a threshold power level or when the power supplied to the APU falls below a threshold power level. Similar to that described above, if the PPS is unable to meet the power demands of the PPU and the APU, the IPS can enter the APU mode 906 and supply additional power from the TEG to the APU.

In another embodiment, the APU receives power from a power source different than the PPS. In this embodiment, the APU can receive power from the TEG, and the IPS can switch to the APU mode 906 when the power supplied to the APU from another power source falls below a threshold power level. In the APU mode 906, the IPS supplies power to the APU from the TEG. In addition, in an embodiment, the PPS can also supply power to the APU during the APU mode 906 if the amount of power supplied by the PPS exceeds the demands of the PPU. Furthermore, the IPS can operate in the APU mode 906 until one or more criteria are met, for example, if there are no auxiliary power users, the power demands of the APU have been fulfilled, or if power supplied by the PPS meets or exceeds the demands by the APU.

Another mode in which the IPS can operate is the ASD mode 908, in which the TEG is operatively connected to one or more of storage devices. Various criteria can cause the IPS to enter the ASD mode 908, such as supply by the PPS exceeding demand by the PPU and the APU. In another embodiment, the ASD mode 908 is the initial mode for IPS. In the ASD mode 908, the TEG collects thermal power and generates electrical power from the thermal power. The generated electrical energy is stored in an electrical energy storage device. In addition, while in the ASD mode 908, the IPS can store thermal energy in thermal energy storage devices. The IPS operates in the ASD mode 908 until one or more criteria are met, for example, until the storage devices are at maximum capacity.

Another mode in which the IPS can operate is the power distribution infrastructure (PDI) mode, in which the TEG is operatively connected to a power distribution infrastructure and provides electrical power to the local grid. Any number of different criteria can cause the IPS to enter the PDI mode 910, such as the storage devices being at full capacity, a beneficial sell price of power sold to the grid, and the like. While in the PDI mode 910, the TEG provides power to the local grid. In addition, in some embodiments, excess power generated by the PPS can also be returned to the grid. The IPS operates in the ASD mode 908 until one or more criteria are met, such as the storage devices being depleted, demand by the PPU and/or the APU exceeding supply by the PPS, and the like.

While some criteria have been described for changing the operation mode of the IPS, there are many other criteria for determining the appropriate mode in which to operate. For example, the criteria can include, but is not limited to, user action or inaction, current price of electricity sold back to the local grid, current electricity usage by the PPU and the APU, storage capacity, upcoming demand by the PPU, the APU, or the local grid, time of day, weather conditions, and future electrical; power production and demand estimates. In certain embodiments, the criteria can also be user-specified or user-adjusted according to preference, instead of being controlled by the electrical controller unit. The order in which the modes operate may depend on criteria set by the controller unit.

In one embodiment, one or more criteria are set by weather reports. In some embodiments, if the weather report displays an incoming weather patterns that lower the power output of the PPS, the IPS switches between the base mode 902 to the ASD mode 908 in order to store as much electrical energy as possible prior to the arrival of the undesirable weather.

In another embodiment, one or more criteria are based on the current price of electrical power sold back to the local grid. In some embodiments, a price for selling power to the grid can be set to increase profit. Thus, the IPS can remain in the ASD mode 908 until the price is met. In some embodiments, if the storage devices are not charged, but the price is met, the IPS can sell power to the grid to increase profits. In some embodiments, other criteria are used, such as, for example, criteria based on usage by the local grid and/or not based on the price level. For example, for the time period when the local grid uses a relatively large amount of electrical power, the IPS can switch between the APU mode 906 and the PDI mode 910.

In addition, priorities between the different modes can be set. For example, providing power to the PPU may have a higher priority than providing power to the APU. Thus, before entering the APU mode 906, the IPS may analyze whether a PPU demands additional power.

In another embodiment, the criteria is set to only satisfy the electrical power demands of the PPU, and not provide energy to the local grid. In such an embodiment, the IPS will be set to only switch to the PDI mode 910, and connect the TEG to the power distribution infrastructure or local grid, when all other demands have been fulfilled.

In yet another embodiment, the criterion can be set to improve the value of a kWh of electricity. In this embodiment, the system switches to the PDI mode 910 based on an analysis of the price of electricity over a given period of time, regardless of whether the criteria for the other modes have been satisfied. When the price of electricity reaches a certain level, the system switches to the PDI mode 910, and provides electrical power to the local grid in order to improve the value of the electrical power. Other orderings of the PPU mode 904, the APU mode 906, ASD mode 908, and the PDI mode 910 are possible based on the numerous possible permutations of criteria, providing the owner of the IPS with a large amount of flexibility with regards to the use of the system. As shown, any number of criteria may be designed for the controller to follow, allowing multiple permutations of the modes.

Reference throughout this specification to “some embodiments,” “certain embodiments,” or “an embodiment” means that a particular feature, structure or characteristic described in connection with the embodiment is included in at least some embodiments. Thus, appearances of the phrases “in some embodiments” or “in an embodiment” in various places throughout this specification are not necessarily all referring to the same embodiment and may refer to one or more of the same or different embodiments. Furthermore, the particular features, structures or characteristics may be combined in any suitable manner, as would be apparent to one of ordinary skill in the art from this disclosure, in one or more embodiments.

As used in this application, the terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

Similarly, it should be appreciated that in the above description of embodiments, various features are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that any claim require more features than are expressly recited in that claim. Rather, inventive aspects lie in a combination of fewer than all features of any single foregoing disclosed embodiment.

The various illustrative logical blocks, modules, data structures, and processes described herein may be implemented as electronic hardware, computer software, or combinations of both. To clearly illustrate this interchangeability of hardware and software, various illustrative components, blocks, modules, and states have been described above generally in terms of their functionality. However, while the various modules are illustrated separately, they may share some or all of the same underlying logic or code. Certain of the logical blocks, modules, and processes described herein may instead be implemented monolithically.

The various illustrative logical blocks, modules, data structures, and processes described herein may be implemented or performed by a machine, such as a computer, a processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor may be a microprocessor, a controller, a microcontroller, a state machine, combinations of the same, or the like. A processor may also be implemented as a combination of computing devices—for example, a combination of a DSP and a microprocessor, a plurality of microprocessors or processor cores, one or more graphics or stream processors, one or more microprocessors in conjunction with a DSP, or any other such configuration.

The blocks or states of the processes described herein may be embodied directly in hardware, in a software module executed by a processor, or in a combination of the two. For example, each of the processes described above may also be embodied in, and fully automated by, software modules executed by one or more machines such as computers or computer processors. A module may reside in a computer-readable storage medium such as RAM memory, flash memory, ROM memory, EPROM memory, EEPROM memory, registers, a hard disk, a removable disk, a CD-ROM, memory capable of storing firmware, or any other form of computer-readable storage medium. An exemplary computer-readable storage medium can be coupled to a processor such that the processor can read information from, and write information to, the computer readable storage medium. In some embodiments, the computer-readable storage medium may be integral to the processor. The processor and the computer-readable storage medium may reside in an ASIC.

Depending on the embodiment, certain acts, events, or functions of any of the processes or algorithms described herein can be performed in a different sequence, may be added, merged, or left out altogether. Thus, in certain embodiments, not all described acts or events are necessary for the practice of the processes. Moreover, in certain embodiments, acts or events may be performed concurrently, e.g., through multi-threaded processing, interrupt processing, or via multiple processors or processor cores, rather than sequentially.

Conditional language used herein, such as, among others, “can,” “could,” “might,” “may,” “e.g.,” and the like, unless specifically stated otherwise, or otherwise understood within the context as used, is intended in its ordinary sense and is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous, are used in their ordinary sense, and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list. Conjunctive language such as the phrase “at least one of X, Y and Z,” unless specifically stated otherwise, is understood with the context as used in general to convey that an item, term, element, etc. may be either X, Y or Z. Thus, such conjunctive language is not generally intended to imply that certain embodiments require at least one of X, at least one of Y and at least one of Z to each be present.

It should be appreciated that in the above description of embodiments, various features are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that any claim require more features than are expressly recited in that claim. Moreover, any components, features, or steps illustrated and/or described in a particular embodiment herein can be applied to or used with any other embodiment(s). Further, no component, feature, step, or group of components, features, or steps are necessary or indispensable for each embodiment. Thus, it is intended that the scope of the inventions herein disclosed and claimed below should not be limited by the particular embodiments described above, but should be determined only by a fair reading of the claims that follow.

What is claimed is:

1. An energy management system comprising:
a primary power source (PPS) configured to provide power to a primary power user (PPU);
a solid state power generation system (SSG) configured to generate electrical power from relative temperature differences; and
an electronic controller unit (ECU) configured to implement a power distribution protocol;
wherein the power distribution protocol is configured to operatively connect the SSG to the PPU, upon the occurrence one or more power usage factors.

2. The energy management system of claim 1, wherein the one or more power usage factors comprises the power output of the PPS falling below a threshold power level.

3. The energy management system of claim 2, wherein the threshold power level is determined based on at least one of previous average power output levels, expected power output levels, and demand by the PPU.

4. The energy management system of claim 1, wherein the ECU is configured to operatively connect the SSG to an auxiliary power user (APU) upon the occurrence of a one or more additional power usage factors.

5. The energy management system of claim 4, wherein the one or more additional power usage factors comprise the power demanded by APU exceeding the power supplied to the APU.

6. The energy management system of claim 4, wherein at least one of the one or more additional power usage factors is the same as the first one or more power usage factors.

7. The energy management system of claim 4, wherein the APU receives power from a power source other than the PPS.

8. The energy management system of claim 1, further comprising an energy storage device.

9. The energy management system of claim 8, wherein the energy storage device stores heat from the heat source.

10. The energy management system of claim 8, wherein the energy storage device stores electrical energy generated by the SSG.

11. The energy management system of claim 1, wherein the ECU is configured to operatively connect the SSG to a power distribution grid (PDI).

12. The energy management system of claim 11, wherein the PDI is a local power grid.

13. The energy management system of claim 1, wherein the SSG is located in close proximity to at least one of the PPU and the PPS.

14. The energy management system of claim 1, wherein the SSG is located remotely from at least one of the PPU and the PPS.

15. The energy management system of claim 1, wherein the ECU is located remotely from at least one of the PPU and the PPS.

16. The energy management system of claim 1, wherein the ECU is embedded as part of at least one of the SSG and the PPS.

17. The energy management system of claim 1, wherein the heat source is one of a machine, a roof, ambient air, and ground.

18. The energy management system of claim 1, wherein the ECU is in communication with multiple SSGs.

19. The energy management system of claim 1, wherein the SSG comprises one or more thermoelectric power generation systems.

20. The energy management system of claim 1, wherein the PPS comprises a solid oxide fuel cell.

21. The energy management system of claim 1, further comprising a secondary burner configured to provide heat to the SSG when the PPS is not fully operational.

22. A method for supplying power to a primary power user, the method comprising:
supplying power from a fluctuating power source (FPS) to a primary power user (PPU);
monitoring the power output of the FPS; and
adjusting supply of power to the PPU according to a power distribution protocol, wherein the power distribution protocol comprises operatively connecting a solid state power generation system (SSG) to the PPU, according to one or more power usage factors.

23. The method of claim 20, wherein the one or more power usage factors comprises the power output of the FPS falling below a threshold power level.

24. A thermoelectric power generation system (TEG) configured to supply power to a primary power user (PPU), the system comprising:
a thermoelectric device configured to generate electrical energy using temperature differentials when coupled to a heat source; and
an electronic controller unit (ECU) configured to direct the electrical energy generated by the thermoelectric device to a primary power user (PPU) upon receiving a communication that the power output of a fluctuating power source (FPS) connected to the PPU is below a threshold power level.
